(19) United States
(12) Patent Application Publication
(10) Pub. No.: US 2026/0066006 A1
(43) Pub. Date: Mar. 5, 2026

(54) MEMORY DEVICES AND OPERATION METHODS THEREOF, MEMORY SYSTEMS AND STORAGE MEDIA

(71) Applicant: Yangtze Memory Technologies Co., Ltd., Wuhan (CN)

(72) Inventors: Ya Wang, Wuhan, Hubei (CN); Wei Qi, Wuhan, Hubei (CN); Junyi Liao, Wuhan, Hubei (CN); Da Li, Wuhan, Hubei (CN); XiangNan Zhao, Wuhan, Hubei (CN)

(21) Appl. No.: 19/051,007

(22) Filed: Feb. 11, 2025

(30) Foreign Application Priority Data
Aug. 29, 2024 (CN) 202411207799.1

(51) Int. Cl. G11C 16/28; G11C 16/04

(52) U.S. Cl. CPC G11C 16/28; G11C 16/0483

(57) ABSTRACT

Examples of the present disclosure provide a memory device, an operation method thereof, a memory system and a storage medium. The memory device includes a memory cell array including: a plurality of memory cells, and a peripheral circuit coupled with the memory cell array and configured to apply a read voltage to a selected word line coupled to a target memory cell of the plurality of memory cells and apply a pass voltage to a non-selected word line adjacent to the selected word line when performing a read operation on the target memory cell, wherein the pass voltage is related to the read voltage and a working temperature of the memory device when the read operation is performed.

### CROSS-REFERENCE TO RELATED APPLICATIONS

This application claims priority to and the benefit of Chinese Patent Application 202411207799.1, filed on Aug. 29, 2024, which is hereby incorporated by reference in its entirety.

### TECHNICAL FIELD

Examples of the present disclosure relate to the field of semiconductor technology, and particularly to memory devices and operation methods thereof, memory systems and storage media.

### BACKGROUND

A memory device is a storage apparatus for saving information in the modern information technology. As a typical non-volatile semiconductor memory, NAND (Not-And) memory has gradually become a mainstream product in the memory market due to its high storage density, controllable production costs, proper programming and erasing speeds and data retention properties.

### BRIEF DESCRIPTION OF THE DRAWINGS

FIG. 1 is a schematic diagram of an example system having a memory system according to an example of the present disclosure;

FIG. 2A is a schematic diagram of an example memory card having a memory system according to an example of the present disclosure;

FIG. 2B is a schematic diagram of an example solid state drive having a memory system according to an example of the present disclosure;

FIG. 3A is a schematic distribution diagram of memory cells of a three-dimensional NAND memory according to an example of the present disclosure;

FIG. 3B is a schematic diagram of an example memory comprising a peripheral circuit according to an example of the present disclosure;

FIG. 4 is a schematic cross-sectional view of a memory cell array comprising a NAND memory string according to an example of the present disclosure;

FIG. 5 is a schematic diagram of an example memory device comprising a memory cell array and a peripheral circuit according to an example of the present disclosure;

FIG. 6 is a schematic structure diagram of an electronic apparatus provided by an example of the present disclosure;

FIG. 7 is a schematic distribution diagram of threshold voltages of a plurality of double-level cells provided by an example of the present disclosure;

FIG. 8 is a schematic distribution diagram of threshold voltages of a plurality of trinary-level cells provided by an example of the present disclosure;

FIG. 9 is a schematic distribution diagram of threshold voltages of a plurality of quad-level cells provided by an example of the present disclosure;

FIG. 10 is a graph of voltage characteristics applied to a non-selected word line at different temperatures provided by an example of the present disclosure; and

FIG. 11 is a schematic distribution diagram of threshold voltages of a memory cell in different read operations provided by an example of the present disclosure.

In the above drawings (not necessarily drawn to scale), like reference numerals may denote like components in different views. Like reference numerals with different letter suffixes may represent different examples of like components. The drawings generally illustrate various examples discussed herein by way of example rather than limitation.

### DETAILED DESCRIPTION

Example implementations disclosed in the present disclosure will be described below in more details with reference to the drawings. Although the example implementations of the present disclosure are shown in the drawings, it is to be understood that the present disclosure may be implemented in various forms and should not be limited by the specific implementations set forth herein. Rather, these implementations are provided for a more thorough understanding of the present disclosure, and to fully convey the scope disclosed by the present disclosure to those skilled in the art.

In the following description, numerous specific details are given in order to provide a more thorough understanding of the present disclosure. However, it is apparent to those skilled in the art that the present disclosure may be practiced without one or more of these details. In other examples, in order to avoid confusion with the present disclosure, some technical features well-known in the field are not described. That is, all the features of the actual examples are not described herein, and well-known functions and structures are not described in detail.

In the drawings, the size and relative size of a layer, an area, and an element may be exaggerated for clarity. Like reference numerals denote like elements throughout the drawings.

It should be understood that when an element or a layer is referred to as being “on”, “adjacent to”, “connected to”, or “coupled to” other elements or layers, it may be directly on, adjacent to, connected to, or coupled to the other elements or layers, or intervening elements or layers may be present. In contrast, when an element is referred to as being “directly on”, “immediately adjacent to”, “directly connected to”, or “directly coupled to” other elements or layers, no intervening elements or layers are present. It should be understood that, although the terms first, second, third, etc. may be used to describe various elements, components, areas, layers, and/or portions, these elements, components, areas, layers, and/or portions should not be limited by these terms. These terms are only used to distinguish one element, component, area, layer or portion from another element, component, area, layer or portion. Thus, a first element, component, area, layer or portion discussed below may be denoted as a second element, component, area, layer or portion, without departing from the teachings of the present disclosure. When the second element, component, area, layer or portion is discussed, it does not mean that the first element, component, area, layer or portion is necessarily present in the present disclosure.

The spatially relative terms, such as “beneath”, “below”, “lower”, “under”, “over” “upper”, and the like, may be used herein for ease of description to describe one element or feature's relationship to other elements or features as illustrated in the figures. It should be understood that in addition to orientations shown in the figures, the spatial relationship terms are intended to further include the different orientations of a device in use and operation. For example, if the device in the drawings is turned over, then the elements or the features described as “below” or “under” or “beneath” other elements may be oriented “on” the other elements or features. Therefore, the example terms “below” and “beneath” may comprise both upper and lower orientations. The device may be orientated otherwise (rotated by 90 degrees or in other orientations), and the spatially descriptive terms used herein are interpreted accordingly.

The terms used herein are only intended to describe the specific examples, and are not used as limitations of the present disclosure. As used herein, unless otherwise indicated expressly in the context, “a”, “an” and “the” in a singular form are also intended to include a plural form. It should also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or” includes any or all combinations of the listed relevant items.

In order to have a more thorough understanding of the characteristics and the technical contents of the examples of the present disclosure, implementation of the examples of the present disclosure is set forth in detail below in conjunction with the drawings, and the appended drawings are only used for reference and illustration, instead of being used to limit the examples of the present disclosure.

A memory device in examples of the present disclosure includes, but is not limited to, a three-dimensional NAND memory. For ease of understanding, the three-dimensional NAND memory is used as an example for description.

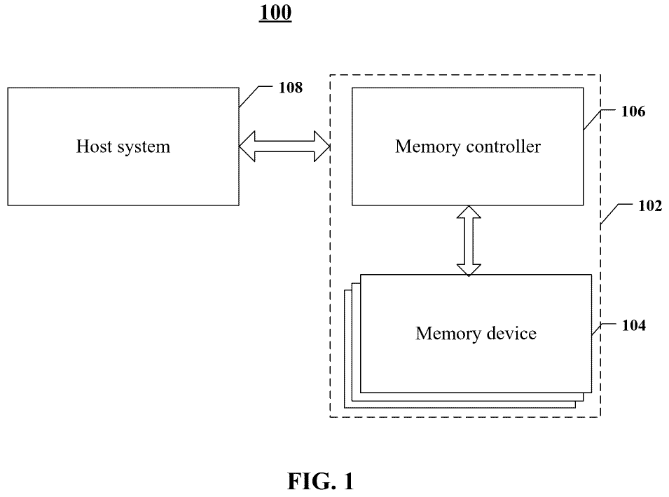

FIG. 1 illustrates a block diagram of an example system 100 having a memory device according to some aspects of the present disclosure. The system 100 may be a mobile phone, a desktop computer, a laptop computer, a tablet computer, a vehicle computer, a gaming console, a printer, a positioning apparatus, a wearable electronic apparatus, a smart sensor, a Virtual Reality (VR) apparatus, an Augmented Reality (AR) apparatus, or any other suitable electronic apparatus having a memory therein. As shown in FIG. 1, the system 100 may comprise a host system 108 and a memory system 102, wherein the memory system 102 has one or more memory devices 104 and a memory controller 106. The host system 108 may be a processor (e.g., a Central Processing Unit (CPU)) of an electronic device or a System-on-Chip (SoC) (e.g., an Application Processor (AP)). The host system 108 may be configured to send or receive data to or from the memory device 104.

According to some implementations, the memory controller 106 is coupled to the memory device 104 and the host system 108, and is configured to control the memory device 104. The memory controller 106 can manage data stored in the memory device 104, and communicate with the host system 108. In some implementations, the memory controller 106 is designed for operating in a low duty-cycle environment, such as Secure Digital (SD) cards, Compact Flash (CF) Cards, Universal Serial Bus (USB) flash drives, or other media for use in electronic apparatuses, such as personal computers, digital cameras, mobile phones, etc. In some implementations, the memory controller 106 is designed for operating in high duty-cycle environment Solid State Disks (SSDs) or embedded Multi-Media Cards (eMMCs) used as data memories for mobile apparatuses, such as smartphones, tablet computers, laptop computers, etc., and enterprise memory arrays.

The memory controller 106 may be configured to control operations of the memory device 104, such as read, erase, and program operations. The memory controller 106 may be further configured to manage various functions with respect to data stored or to be stored in the memory device 104, including, but not limited to, bad block management, garbage collection, logical-to-physical address conversion, and wear leveling, etc. In some implementations, the memory controller 106 is further configured to process an error correction code (ECC) with respect to the data read from or written to the memory device 104. The memory controller 106 may perform any other suitable functions as well, for example, formatting the memory device 104. The memory controller 106 may communicate with an external apparatus (e.g., the host system 108) according to a particular communication protocol. For example, the memory controller 106 may communicate with the external apparatus through at least one of various interface protocols, such as a USB protocol, an MMC protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer Small Interface (SCSI) protocol, an Enhanced Small Disk Interface (ESDI) protocol, an Integrated Drive Electronics (IDE) protocol, a Firewire protocol, etc.

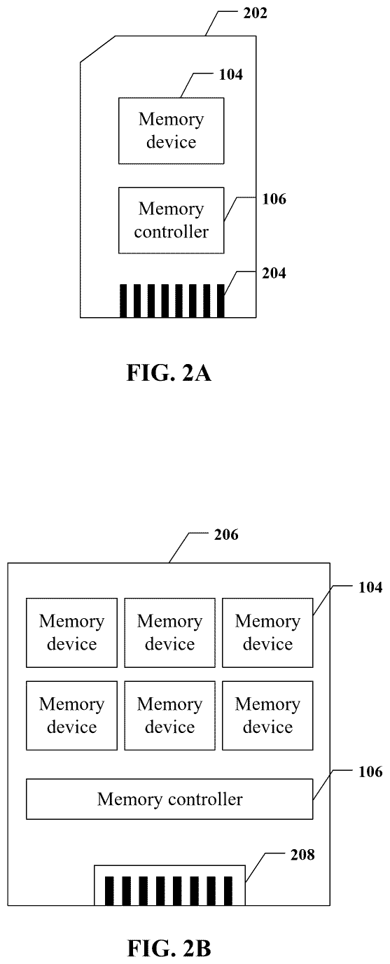

The memory controller 106 and one or more memory devices 104 can be integrated into various types of storage apparatuses, for example, be included in the same package, such as a Universal Flash Storage (UFS) package or an eMMC package. That is to say, the memory system 102 may be implemented and packaged into different types of end electronic products. In an example as shown in FIG. 2a, the memory controller 106 and a single memory device 104 may be integrated into a memory card 202. The memory card 202 may comprise a PC card (PCMCIA, Personal Computer Memory Card International Association), a CF card, a Smart Media (SM) card, a memory stick, a Multimedia card (MMC, RS-MMC, and MMCmicro), an SD card (SD, miniSD, microSD, and SDHC), a UFS, etc. The memory card 202 may further comprise a memory card connector 204 coupling the memory card 202 with a host (e.g., the host system 108 in FIG. 1). In another example as shown in FIG. 2b, the memory controller 106 and a plurality of memory devices 104 may be integrated into an SSD 206. The SSD 206 may further comprise an SSD connector 208 coupling the SSD 206 with a host (e.g., the host system 108 in FIG. 1). In some implementations, the storage capacity and/or operation speed of the SSD 206 are greater than those of the memory card 202.

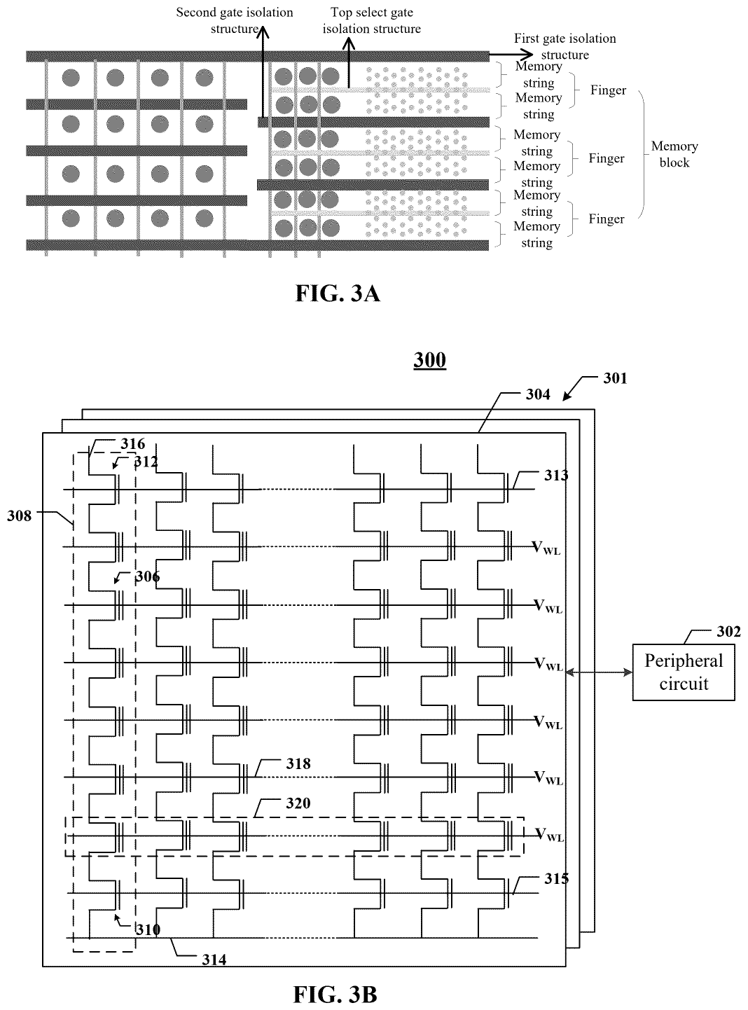

FIG. 3a gives an example of a schematic structural diagram of a memory cell array of a three-dimensional NAND memory. As shown in FIG. 3a, the cell array of the three-dimensional NAND memory is constituted by a plurality of rows of memory cells that are staggered in parallel and are parallel to a gate isolation structure. Every two rows of memory cells are separated by the gate isolation structure and a top select gate isolation structure. Each row of memory cells comprises a plurality of memory cells. The gate isolation structure may comprise a first gate isolation structure and a second gate isolation structure. The first gate isolation structure divides the memory cell array into a plurality of memory blocks. The plurality of second gate isolation structures may divide the memory block into a plurality of fingers. The top select gate isolation structure disposed in the middle of each finger may divide the finger into two parts, thereby dividing the finger into two memory strings. One memory block as shown in FIG. 3a comprises six memory strings. In the practical application, the number of the memory strings in one memory block is not limited thereto.

In some examples, each memory block may be coupled to a plurality of word lines. A plurality of memory cells coupled to each separately controlled word line constitute a page. In an example, all memory cells in each memory string in FIG. 3a are coupled to constitute one page.

It is to be noted that the number of the rows of memory cells between the gate isolation structure and the top select gate isolation structure in FIG. 3a is only an example, and is not used to limit the number of the rows of memory cells comprised in one finger of the three-dimensional NAND memory in the present disclosure. In the practical applications, the number of the rows of memory cells included in one finger may be adjusted to, for example, 2, 4, 8, and 16, etc., according to practical situations.

FIG. 3b shows a schematic circuit diagram of an example memory device 300 comprising a peripheral circuit according to some aspects of the present disclosure. The memory device 300 may be an example of the memory device 104 in FIG. 1. The memory device 300 may comprise a memory cell array 301 and a peripheral circuit 302 coupled to the memory cell array 301. The memory cell array 301 as a three-dimensional NAND memory array is illustrated as an example, wherein memory cells 306 are NAND memory cells, and are provided in an array of memory strings 308, and each memory string 308 extends above a substrate (not shown) vertically. In some implementations, each memory string 308 comprises a plurality of memory cells 306 coupled in series and stacked vertically. Each memory cell 306 may maintain a continuous analog value, such as voltage or charge, which depends on the number of electrons trapped within a region of the memory cell 306. Each memory cell 306 may be a floating gate type memory cell that comprises a floating gate transistor, or a charge trapping type memory cell that comprises a charge trapping transistor.

In some implementations, each memory cell 306 is a single-level cell (SLC) that has two possible storage states and thus may store one bit of data. For example, a first storage state “0” may correspond to a first voltage range, and a second storage state “1” may correspond to a second voltage range. In some implementations, each memory cell 306 is a Multi-Level Cell (MLC) that can store more than one bit of data in more than four storage states. For example, the MLC can store two bits per cell (also referred to as a double-level cell), three bits per cell (also referred to as a trinary-level cell (TLC)), four bits per cell (also referred to as a quad-level cell (QLC)), five bits per cell (also referred to as a penta-level cell (PLC)), or more than five bits per cell. Each MLC can be programmed to assume a range of possible nominal storage values. In one example, if each MLC stores two bits of data, the MLC can be programmed to employ one of three possible program levels from an erase state by writing one of three possible nominal storage values to the cell, and a fourth nominal storage value may be used for the erase state.

As shown in FIG. 3b, each memory string 308 may comprise a bottom select transistor 310 (also referred to as a source select transistor BSG, and comprising a source select gate) at its source terminal and a top select transistor 312 (also referred to as a drain select transistor TSG, and comprising a drain select gate) at its drain terminal. The source select transistor BSG 310 and the drain select transistor TSG 312 may be configured to activate a selected memory string 308 during a read operation and a program operation. In some implementations, sources of the memory strings 308 in the same memory block 304 are coupled through the same source line (SL) 314 (e.g., a common SL). In other words, according to some implementations, all the memory strings 308 in the same memory block 304 have an array common source (ACS). According to some implementations, the TSG 312 of each memory string 308 is coupled to a corresponding bit line (BL) 316, and data may be read or written from the bit line 316 via an output bus (not shown). In some implementations, each memory string 308 is configured to be selected or unselected by applying a select voltage (e.g., above a threshold voltage of a transistor having the TSG 312) or an unselect voltage (e.g., 0 V) to the corresponding TSG 312 via one or more TSG lines 313 and/or by applying a select voltage (e.g., above a threshold voltage of a transistor having the BSG 310) or an unselect voltage (e.g., 0 V) to the corresponding BSG 310 via one or more BSG lines 315.

As shown in FIG. 3b, the memory strings 308 may be organized into a plurality of memory blocks 304, and each of the plurality of memory blocks 304 may have a common source line 314 (e.g., coupled to the ground). In some implementations, each memory block 304 is a basic data unit for an erase operation, e.g., all the memory cells 306 on the same memory block 304 are erased at the same time. In order to erase the memory cells 306 in a selected memory block 304, the source line 314 coupled to the selected memory block 304 as well as unselected memory blocks 304 that are in the same plane as the selected memory block 304 may be biased with an erase voltage (Vers) (e.g., a high positive voltage (such as 20 V or higher)). It is to be understood that in some examples, the erase operation may be performed at a half memory block level, a quarter memory block level, or a level having any suitable number of memory blocks or any suitable fraction of a memory block. The memory cells 306 of adjacent ones of the memory strings 308 may be coupled through the word line 318 that selects which row of memory cells 306 is affected by the read and program operations. In some implementations, in conjunction with FIG. 3a above, a plurality of memory cells are isolated by the top select gate isolation structure and the gate isolation structure. The plurality of memory cells between the top select gate isolation structure and the gate isolation structure are arranged into a plurality of rows of memory cells, and each row of memory cells is parallel to the gate isolation structure and the top select gate isolation structure.

With reference to FIGS. 3a and 3b, each of the plurality of cells 306 is coupled to the corresponding word line 318, and each memory string 308 is coupled to the corresponding bit line 316 through a corresponding select transistor (e.g., the drain select transistor (TSG) 312).

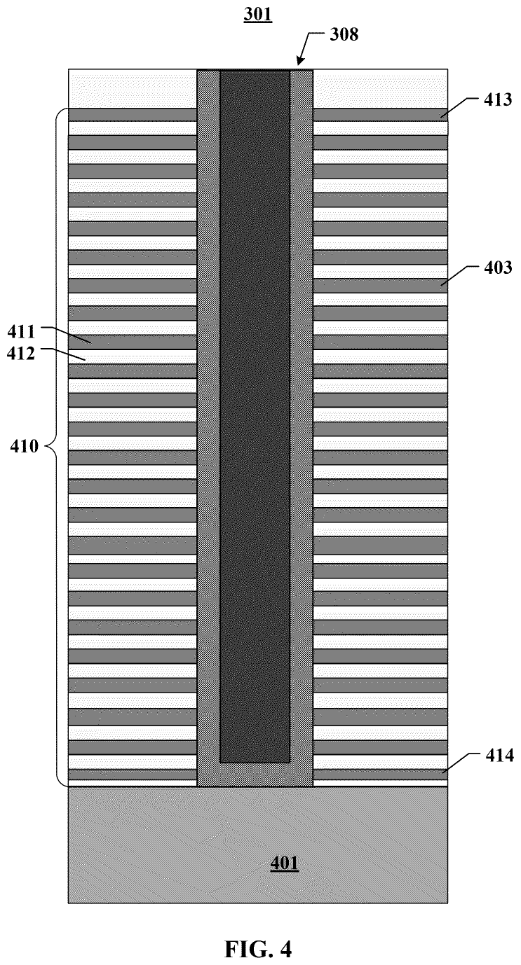

FIG. 4 shows a schematic cross-sectional view of an example memory cell array 301 comprising a memory string 308 with NAND as an example according to some aspects of the present disclosure. As shown in FIG. 4, the NAND memory cell array 301 may comprise a stack structure 410. The stack structure 410 comprises a plurality of gate layers 411 and a plurality of insulating layers 412 that are stacked sequentially and alternately, and a channel structure that extends through the gate layers 411 and the insulating layers 412 vertically, wherein the channel structure is coupled with each gate layer to constitute a memory cell, and is coupled with the plurality of gate layers in the stack structure 410 to constitute the memory string 308. The gate layers 411 and the insulating layers 412 may be alternately stacked, and two adjacent ones of the gate layers 411 are separated by one insulating layer 412.

A composition material of the gate layer 411 may comprise a conductive material. The conductive material includes, but is not limited to, tungsten (W), cobalt (Co), copper (Cu), aluminum (Al), polysilicon, doped silicon, silicides, or any combination thereof. In some implementations, each gate layer 411 comprises a metal layer, e.g., a tungsten layer. In some implementations, each gate layer 411 comprises a doped polysilicon layer. Each gate layer 411 may comprise a control gate surrounding the memory cell. The gate layer 411 at the top of the stack structure 410 may extend laterally as a top select gate line; the gate layer 411 at the bottom of the stack structure 410 may extend laterally as a bottom select gate line; and the gate layer 411 extending laterally between the top select gate line and the bottom select gate line may serve as a word line layer.

In some examples, the stack structure 410 may be disposed on a substrate 401. The substrate 401 may comprise silicon (e.g., single crystalline silicon), silicon germanium (SiGe), gallium arsenide (GaAs), germanium (Ge), silicon on insulator (SOI), germanium on insulator (GOI), or any other suitable materials.

In some examples, the memory string 308 comprises a channel structure that extends through the stack structure 410 vertically. In some implementations, the channel structure comprises a channel hole filled with semiconductor material(s) (e.g., as a semiconductor channel) and dielectric material(s) (e.g., as a memory film). In some implementations, the semiconductor channel comprises silicon, e.g., polysilicon. In some implementations, the memory film is a composite dielectric layer comprising a tunneling layer, a storage layer (also referred to as a “charge trapping/storage layer”), and a barrier layer. The channel structure may have a cylindrical shape (e.g., a pillar shape). According to some implementations, the semiconductor channel, the tunneling layer, the storage layer, and the barrier layer are arranged radially from the center toward the outer surface of the pillar in this order. The tunneling layer may comprise silicon oxide, silicon oxynitride, or any combination thereof. The storage layer may comprise silicon nitride, silicon oxynitride, or any combination thereof. The barrier layer may comprise silicon oxide, silicon oxynitride, a high dielectric constant (high-k) dielectric, or any combination thereof. In an example, the memory film may comprise a composite layer of silicon oxide/silicon oxynitride/silicon oxide (ONO).

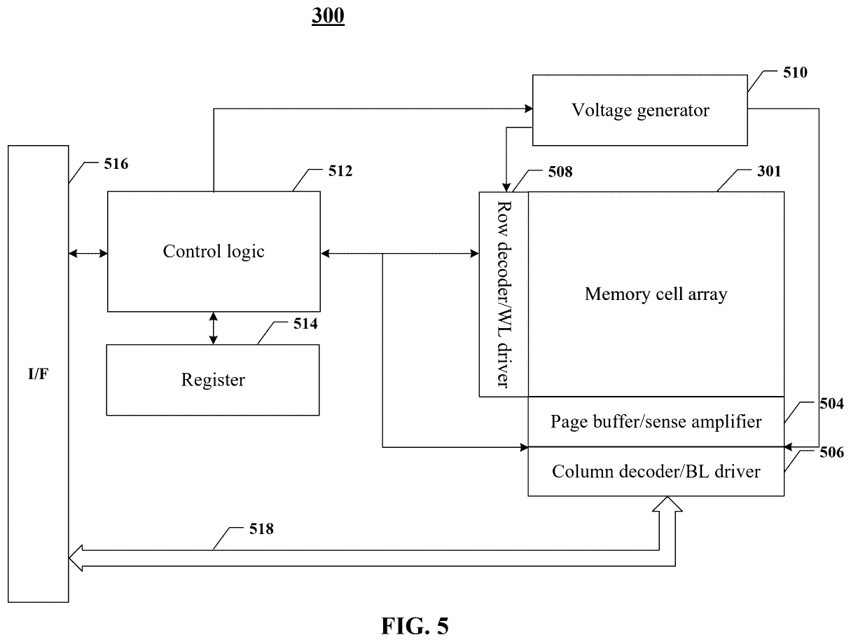

Referring back to FIG. 3b, the peripheral circuit 302 may be coupled to the memory cell array 301 through the bit line 316, the word line 318, the source line 314, the BSG line 315 and the TSG line 313. The peripheral circuit 302 may comprise any suitable analog, digital, and hybrid signal circuits for facilitating operations of the memory cell array 301 by applying and sensing at least one of a voltage signal or a current signal to and from each target memory cell 306 via the bit line 316, the word line 318, the source line 314, the BSG line 315, and the TSG line 313. The peripheral circuit 302 may comprise various types of peripheral circuits formed using a metal-oxide-semiconductor (MOS) technology. For example, FIG. 5 shows some example peripheral circuits. The peripheral circuit 302 comprises a page buffer/sense amplifier 504, a column decoder/bit line driver 506, a row decoder/word line driver 508, a voltage generator 510, a control logic 512, a register 514, an interface 516, and a data bus 518. It is to be understood that, in some examples, an additional peripheral circuit not shown in FIG. 5 may be also included.

The page buffer/sense amplifier 504 may be configured to read and program (write) data from and to the memory cell array 301 according to a control signal from the control logic 512. In one example, the page buffer/sense amplifier 504 may store program data (write data) to be programmed into the memory cell array 301. In another example, the page buffer/sense amplifier 504 may perform a program verification operation to ensure that the data has been properly programmed into the memory cell 306 coupled to the selected word line 318. In yet another example, the page buffer/sense amplifier 504 may also sense a low power signal from the bit line 316 that represents a data bit stored in the memory cell 306, and amplifies a small voltage swing to a recognizable logic level in the read operation. The column decoder/bit line driver 506 may be configured to be controlled by the control logic 512 and select one or more memory strings 308 by applying a bit line voltage generated from the voltage generator 510.

The row decoder/word line driver 508 may be configured to be controlled by the control logic 512, select/unselect the memory block 304 of the memory cell array 301, and select/unselect the word line 318 of the memory block 304. The row decoder/word line driver 508 may be further configured to drive the word line 318 using a word line voltage generated from the voltage generator 510. In some implementations, the row decoder/word line driver 508 may also select/unselect and drive the BSG line 315 and the TSG line 313. As described below in detail, the row decoder/word line driver 508 is configured to perform the program operation on the memory cells 306 that are coupled to the selected word line(s) 318. The voltage generator 510 may be configured to be controlled by the control logic 512 and generate a word line voltage (e.g., a read voltage, a program voltage, a pass voltage, a channel boost voltage, a verify voltage, etc.), a bit line voltage, and a source line voltage to be supplied to the memory cell array 301.

The control logic 512 may be coupled to each of other portions in the peripheral circuit described above, and configured to control operations of each of the other portions in the peripheral circuit. The register 514 may be coupled to the control logic 512 and comprise a state register, a command register and an address register for storing state information, a command operation code (OP code) and a command address for controlling the operation of each peripheral circuit. The interface 516 may be coupled to the control logic 512, and act as a control buffer to buffer and relay control commands received from a host system (not shown) to the control logic 512 and state information received from the control logic 512 to the host system. The interface 516 may be also coupled to the column decoder/bit line driver 506 via the data bus 518, and act as a data I/O interface and a data buffer to buffer or relay data to or from the memory cell array 301.

It is to be noted that with the development of the semiconductor industry, the storage capacity of the memory cell array in the NAND memory gradually increases, and the number of layers of the memory cells in the memory cell array gradually increases, resulting in reduction in channel current and decrease in read window. In addition, due to the influence of the working temperature of the NAND memory, reading the memory cell at high temperature or low temperature easily results in a shift of threshold voltage of the memory cell, thereby further decreasing the read window. In some other examples, with the gradual increase in the number of the layers of memory cells, a spacing between adjacent layers of memory cells is reduced, and a distance between adjacent word lines coupled to the adjacent layers of memory cells is shortened, such that a coupling effect easily occurs between the adjacent word lines when performing the read operation. Meanwhile, other read disturbances, such as weak programming, etc., may be present due to the influence of variation in channel current, which reduces the read performance and reliability of the memory device.

Based on one or more of the above problems, examples of the present disclosure provide a memory device that comprises: a memory cell array comprising a plurality of memory cells, and a peripheral circuit coupled with the memory cell array and configured to apply a read voltage to a selected word line coupled to a target memory cell of the plurality of memory cells and apply a pass voltage to a non-selected word line adjacent to the selected word line when performing a read operation on the target memory cell, wherein the pass voltage is related to the read voltage and a working temperature of the memory device when the read operation is performed.

Before introducing the memory device, the configuration and structure of the memory device is introduced in conjunction with the drawings.

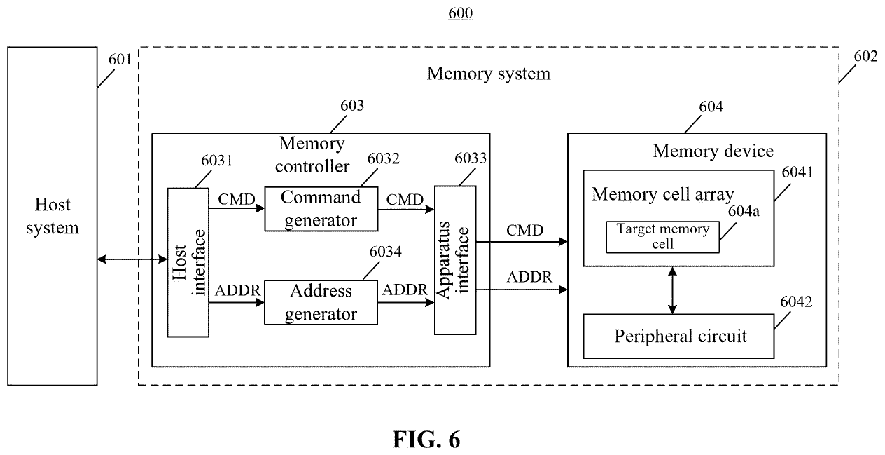

With reference to FIG. 6, FIG. 6 shows a schematic structure diagram of an electronic apparatus. As shown in FIG. 6, the electronic apparatus 600 comprises a host system 601 and a memory system 602. The memory system 602 is connected with the host system 601, and the host system 601 may be an electronic apparatus, such as a personal computer, a mobile terminal, etc. The host system 601 may comprise a host controller and a host memory area, etc. (not labelled in FIG. 6). The memory system 602 may comprise a memory controller 603 and a memory device 604. The memory controller 603 is configured to control the memory device 604 to perform read, write and erase operations, etc., and the memory controller 603 may be coupled with the memory device 604 in any suitable manner.

In some particular examples, the memory controller 603 may receive data, command and address from the host system 601, and send data, command and address to the memory device 604. The memory controller 603 may receive data, command and address from the host system 601 through a host interface 6031, decode the command received from the host interface 6031 through a command generator 6032 to generate an access command CMD, and provide the access command CMD to the memory device 604 through an apparatus interface 6033. The memory controller 603 may decode the address received from the host interface 6031 through an address generator 6034 to generate an address ADDR to be accessed in a memory cell array 6041, and may provide the address ADDR to be accessed to the memory device 604 through the apparatus interface 6033. The access command may be a signal that instructs the memory device 604 to write or read data by accessing one or more memory cells in the memory cell array 6041 corresponding to the address ADDR. Moreover, the memory controller 603 may also send a refresh command to the memory device 604, wherein the refresh command may be a signal that instructs the memory device 604 to read and re-write data by accessing one or more memory cells in the memory cell array 6041 corresponding to the address ADDR.

Referring to FIG. 6, the memory device 604 further comprises a peripheral circuit 6042 coupled with the memory cell array 6041 and comprising a page buffer/sense amplifier circuit, a column decoder/bit line driver, a row decoder/word line driver, a voltage generator, a control logic, a register, an interface and a data bus, etc. Here, the peripheral circuit 6042 may be configured to receive the access command CMD and the address ADDR, access each memory cell in the memory cell array 6041 independently based on resolving the access command CMD and the address ADDR, and perform a read operation, write operation, erase operation or refresh operation, etc. on data stored in the accessed memory cell.

In the examples of the present disclosure, the memory cell array 6041 may comprise a plurality of memory cells that are coupled to a plurality of word lines of the memory device respectively. The accessed memory cell mentioned in the above example may be construed as a target memory cell 604a of the plurality of memory cells. It is to be noted that the plurality of memory cells in the memory cell array may be single-level cells (SLCs), which means that the memory cell may be configured to store one bit of data, or may be multi-level cells (MLCs, TLCs, QLCs, etc.), which means that the memory cell may be configured to store multiple bits of data. For the single-level cell, it needs to apply one order of read voltage to a word line to which the memory cell is coupled during a process of performing the read operation. For the multi-level cell, every time one bit of data in the memory cell is read, it needs to apply at least one order of read voltage to the word line to which the memory cell is coupled during the process of performing the read operation.

The corresponding relationship between the order of read voltage and the number of bits in the multi-level cell is introduced below in detail.

When the memory cell is configured to store M bits of data, the plurality of memory cells in the memory cell array have 2^{M} storage states that are distinguished through N orders of read voltage, the order N of the read voltage equals 2^{M}−1, and both M and N are integers greater than 1.

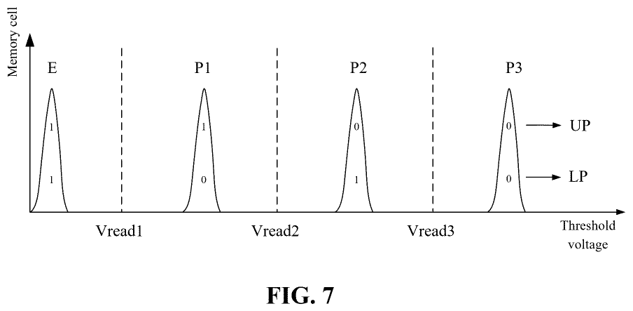

With reference to FIG. 7, FIG. 7 shows a schematic distribution diagram of threshold voltages of a plurality of double-level cells in the memory cell array, wherein the double-level cell needs to read its two bits of data through three orders (3=2²−1) of read voltage when the memory cell is configured to store two bits of data. In an example, the two bits of data stored in the memory cell correspond to four storage states (one erase state E and three program states P1, P2 and P3), that is, four voltage ranges are allocated to four data values. During the reading, the two bits of memory data stored in the memory cell are read by applying three orders of read voltage used for distinguishing the four voltage ranges. Here, M=2, and N=3. It is to be noted that the threshold voltage distribution of each storage state corresponding to the plurality of memory cells follows a normal distribution.

In this case, the memory cell array may comprise an upper page (UP) and a lower page (LP). The two bits of data in each memory cell belong to the upper page and the lower page of the memory cell array respectively. When reading data in the upper page (UP) of the target memory cell, one order of read voltage (e.g., V=_{read2}) needs to be applied to a word line coupled to a target memory cell; and when reading data in the lower page (LP) of the target memory cell, two orders of read voltage (e.g., V_{read1} and V_{read3}) need to be applied to the word line coupled to the target memory cell. That is, the upper page corresponds to one order of read voltage, and the lower page corresponds to two orders of read voltage.

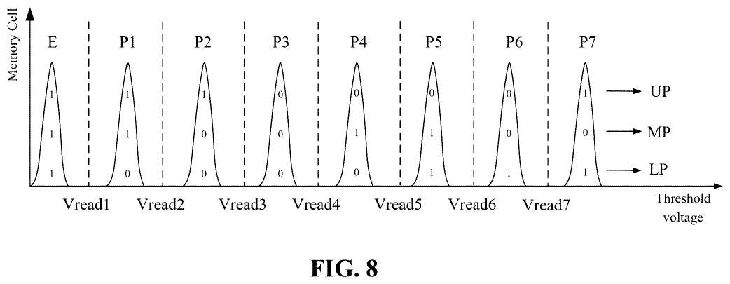

With reference to FIG. 8, FIG. 8 shows a schematic distribution diagram of threshold voltages of a plurality of trinary-level cells in the memory cell array, wherein the trinary-level cell needs to read its three bits of data through seven orders (7=2³−1) of read voltage when the memory cell is configured to store three bits of data. In an example, the three bits of data stored in the memory cell correspond to eight storage states (one erase state E and seven program states P1, P2, P3, P4, P5, P6, and P7), that is, eight voltage ranges are allocated to eight data values. During the reading, the three bits of memory data stored in the memory cell are read by applying the seven orders of read voltage used for distinguishing the eight voltage ranges. Here, M=3, and N=7.

In this case, the memory cell array may comprise an upper page (UP), a middle page (MP) and a lower page (LP). The three bits of data in each memory cell belong to the upper page, the middle page and the lower page of the memory cell array respectively. When reading data in the upper page (UP) of the target memory cell, two orders of read voltage (e.g., V_{read3} and V_{read7}) need to be applied to a word line coupled to a target memory cell; when reading data in the middle page (MP) of the target memory cell, three orders of read voltage (e.g., V_{read2}, V_{read4} and V_{read6}) need to be applied to the word line coupled to the target memory cell; and when reading data in the lower page (LP) of the target memory cell, two orders of read voltage (e.g., V_{read1} and V_{read5}) need to be applied to the word line coupled to the target memory cell. That is, the upper page corresponds to the two orders of read voltage, the middle page corresponds to the three orders of read voltage, and the lower page corresponds to the two orders of read voltage.

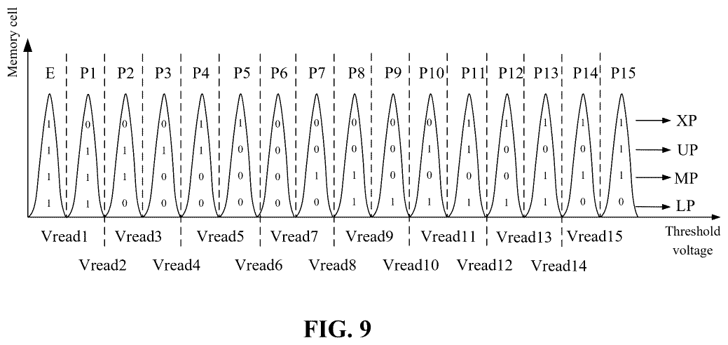

With reference to FIG. 9, FIG. 9 shows a schematic distribution diagram of threshold voltages of a plurality of quad-level cells in the memory cell array, wherein the quad-level cell reads its four bits of data through fifteen orders (15=2⁴−1) of read voltage when the memory cell is configured to store four bits of data. In an example, the four bits of data stored in the memory cell correspond to sixteen storage states (one erase state E and fifteen program states P1, P2, P3, P4, P5, P6, P7, P8, P9, P10, P11, P12, P13, P14, and P15), that is, sixteen voltage ranges are allocated to sixteen data values. During the reading, the four bits of data stored in the memory cell are read by applying the fifteen orders of read voltage used for distinguishing the sixteen voltage ranges. Here, M=4, and N=15.

In this case, the memory cell array may comprise an extra page (XP), an upper page (UP), a middle page (MP) and a lower page (LP). The four bits of data in each memory cell belong to the extra page, the upper page, the middle page and the lower page of the memory cell array respectively. When reading data in the extra page (XP) of the target memory cell, four orders of read voltage (e.g., V_{read1}, V_{read4}, V_{read6} and V_{read11}) need to be applied to a word line coupled to a target memory cell; when reading data in the upper page (UP) of the target memory cell, four orders of read voltage (e.g., V_{read5}, V_{read10}, V_{read12} and V_{read15}) need to be applied to the word line coupled to the target memory cell; when reading data in the middle page (MP) of the target memory cell, four orders of read voltage (e.g., V_{read3}, V_{read7}, V_{ead9} and Vrea_{d13}) need to be applied to the word line coupled to the target memory cell; and when reading data in the lower page (LP) of the target memory cell, three orders of read voltage (e.g., V_{read2}, V_{read8} and V_{read14}) need to be applied to the word line coupled to the target memory cell. That is, the extra page corresponds to the four orders of read voltage, the upper page corresponds to the four orders of read voltage, the middle page corresponds to the four orders of read voltage, and the lower page corresponds to the three orders of read voltage, and so on.

In some other examples, the order of the read voltage corresponding to each kind of page (e.g., the upper page, the lower page, etc.) may also follow another corresponding distribution, which is not limited in the present disclosure.

In the examples of the present disclosure, the peripheral circuit is configured to apply a read voltage to a selected word line coupled to a target memory cell of the plurality of memory cells and apply a pass voltage to a non-selected word line adjacent to the selected word line when performing the read operation on the target memory cell. When the target memory cell is a single-level cell, one order of read voltage and one pass voltage are needed to read one bit of data in the target memory cell, and the one order of read voltage corresponds to the pass voltage. When the target memory cell is a multi-level cell, multiple orders of read voltage and multiple pass voltages are needed to read multiple bits of data in the target memory cell, and the multiple orders of read voltage have a one-to-one correspondence with the multiple pass voltages, that is, each order of read voltage corresponds to one pass voltage. The value of the pass voltage is related to a working temperature of the memory device and the read storage state. As such, the value of the pass voltage applied to the non-selected word line may be determined according to the current working environment and the read storage state of the memory device, so as to reduce the influence of the read storage state and the working temperature on the read operation and improve the read performance and reliability of the memory device.

In some examples, the target memory cell is configured to store M bits of data, and N orders of read voltage are applied to a selected word line coupled to the target memory cell and N pass voltages are applied to a non-selected word line adjacent to the selected word line when performing the read operation on the target memory cell, wherein N=2^{M}−1. Here, the N orders of read voltage correspond to the N pass voltages, and values of at least part of the N pass voltages are different, that is, all the values of the N pass voltages may be different, or part of them may be the same and the other part of them may be different.

In an example, when the target memory cell is a trinary-level cell (TLC) (e.g., M=3), seven orders of read voltage, such as a first read voltage V_{read1}, a second read voltage V_{read2}, a third read voltage V_{read3}, a fourth read voltage V_{read4}, a fifth read voltage V_{read5}, a sixth read voltage V_{read6} and a seventh read voltage V_{read7}, are needed to read the three bits of data in the target memory cell. As described before, values of the seven orders of read voltage are all different, and are arranged in an ascending order sequentially according to the threshold voltage distribution of the storage state, e.g., V_{read1}<V_{read2}<V_{read3}<V_{read4}<V_{read5}<V_{read6}<V_{read7}. Here, seven pass voltages, such as a first pass voltage Vₚₐₛₛ₁, a second pass voltage Vₚₐₛₛ₂, a third pass voltage Vₚₐₛₛ₃, a fourth pass voltage Vₚₐₛₛ₄, a fifth pass voltage Vₚₐₛₛ₅, a sixth pass voltage Vₚₐₛₛ₆ and a seventh pass voltage Vₚₐₛₛ₇, need to be applied to the non-selected word line adjacent to the selected word line. All the values of the seven pass voltages may be different, or part of them may be the same and the other part of them may be different.

In the examples of the present disclosure, the value of the pass voltage is determined by a reference voltage and a compensation voltage. The compensation voltage is related to the read storage state.

In an example, the value of the pass voltage is a sum of a value of the reference voltage and a value of the compensation voltage. The reference voltage is the pass voltage applied to the non-selected word line when the read operation is performed at a reference temperature. Here, the reference voltage is a fixed value. In other words, when the read operation is performed, the value of the reference voltage remains unchanged regardless of which bit of data in the memory cell is read or which order of read voltage is applied to the selected word line. The value of the compensation voltage is a product of a temperature difference between the working temperature of the memory device and the reference temperature and a compensation factor. Here, the compensation factor is a variable which varies with the read storage state, that is, the compensation voltage is a variable.

On this basis, in the examples of the present disclosure, the peripheral circuit is further configured to: determine the reference temperature and the reference voltage; acquire the working temperature of the memory device and determine the temperature difference between the working temperature of the memory device and the reference temperature; and determine the value of the compensation voltage. The reference temperature and the reference voltage may be set according to actual demands. The value of the compensation voltage is the product of the temperature difference between the working temperature of the memory device and the reference temperature and the compensation factor. Here, the N pass voltages correspond to N compensation voltages that correspond to L compensation factors, and L is an integer greater than 1 and is less than or equal to N.

In some examples, a relationship among the pass voltage, the compensation voltage and the compensation factor is:

$${V}_{pass} = {V}_{0} + {V}_{c} = {V}_{0} + {( {T}_{0} - {T}_{1} )}^{*} {T}_{co - n} ;$$

wherein Vₚₐₛₛ is the pass voltage; V₀ is the reference voltage; V_{c} is the compensation voltage; T₀ is the reference temperature; T₁ is the working temperature of the memory device; and T_{co-n}, is the compensation factor.

Here, the reference voltage V₀ and the reference temperature T₀ are fixed values and do not vary with the working temperature and the read storage state. In a practical application, the reference temperature T₀ and the reference voltage V₀ may be determined according to actual demands. For example, the reference temperature T₀ is set as 85° C., and a pass voltage applied to the non-selected word line when the read operation is performed at 85° C. is determined to be the reference voltage V₀.

The compensation voltage V_{c} is a variable and may vary with the working temperature T₁ of the memory device and the compensation factor T_{co-n}. Under the condition that the working temperature T₁ of the memory device is unchanged, the value of the compensation voltage V_{c} is directly proportional to the compensation factor T_{co-n}, while the compensation factor T_{co-n} is related to the read storage state.

In some examples, when the memory cell is configured to store multiple bits of data, multiple storage states are distributed sequentially from a low storage state to a high storage state according to the arrangement of threshold voltages in an ascending order. Voltage values of the multiple orders of read voltage are arranged sequentially in an ascending order, and the multiple compensation factors corresponding to the multiple orders of read voltage are arranged sequentially in a descending order, that is, the multiple compensation voltages corresponding to the multiple orders of read voltage decrease gradually. In other words, the lower the read storage state is, the smaller the read voltage applied to the selected word line is, and the larger the pass voltage applied to the non-selected word line is.

In an example, with reference to FIG. 8, under the condition that the reference voltage V₀, the reference temperature T₀ and the working temperature T₁ of the memory device are unchanged, when the memory cell is a trinary-level cell (TLC) (e.g., M=3), seven orders of read voltage are the first read voltage V_{read1}, the second read voltage V_{read2}, the third read voltage V_{read3}, the fourth read voltage V_{read4}, the fifth read voltage V_{read5}, the sixth read voltage V_{read6} and the seventh read voltage V_{read7} respectively. The values of the seven orders of read voltage are from small to large sequentially, that is, the value of the first read voltage V_{read1} is less than the value of the second read voltage V_{read2}, the value of the second read voltage V_{read2} is less than the value of the third read voltage V_{read3}, the value of the third read voltage V_{read3} is less than the value of the fourth read voltage V_{read4}, the value of the fourth read voltage V_{read4} is less than the value of the fifth read voltage V_{read5}, the value of the fifth read voltage V_{read5} is less than the value of the sixth read voltage V_{read6}, and the value of the sixth read voltage V_{read6} is less than the value of the seventh read voltage V_{read7}, e.g., V_{read1}<V_{read2}<V_{read3}<V_{read4}<V_{read5}<V_{read6}<V_{read7}.

Accordingly, the seven pass voltages are a first pass voltage Vₚₐₛₛ₁ corresponding to the first read voltage V_{read1}, a second pass voltage Vₚₐₛₛ₂ corresponding to the second read voltage V_{read2}, a third pass voltage Vₚₐₛₛ₃ corresponding to the third read voltage V_{read3}, a fourth pass voltage Vₚₐₛₛ₄ corresponding to the fourth read voltage V_{read4}, a fifth pass voltage Vₚₐₛₛ₅ corresponding to the fifth read voltage V_{read5}, a sixth pass voltage Vₚₐₛₛ₆ corresponding to the sixth read voltage V_{read6}, and a seventh pass voltage Vₚₐₛₛ₇ corresponding to the seventh read voltage V_{read7} respectively.

Moreover, the first pass voltage Vₚₐₛₛ₁ corresponds to a first compensation factor T_{co-1}, the second pass voltage Vₚₐₛₛ₂ corresponds to a second compensation factor T_{co-2}, the third pass voltage Vₚₐₛₛ₃ corresponds to a third compensation factor T_{co-3}, the fourth pass voltage Vₚₐₛₛ₄ corresponds to a fourth compensation factor T_{co-4}, the fifth pass voltage Vₚₐₛₛ₅ corresponds to a fifth compensation factor T_{co-5}, the sixth pass voltage Vₚₐₛₛ₆ corresponds to a sixth compensation factor T_{co-6}, and the seventh pass voltage Vₚₐₛₛ₇ corresponds to a seventh compensation factor T_{co-7}.

The first compensation factor T_{co-1}, is greater than the second compensation factor T_{co-2}, the second compensation factor T_{co-2} is greater than the third compensation factor T_{co-3}, the third compensation factor T_{co-3} is greater than the fourth compensation factor T_{co-4}, the fourth compensation factor T_{co-4} is greater than the fifth compensation factor T_{co-5}, the fifth compensation factor T_{co-5} is greater than the sixth compensation factor T_{co-6}, and the sixth compensation factor T_{co-6} is greater than the seventh compensation factor T_{co-7}, e.g., T_{co-1}>T_{co-2}>T_{co-3}>T_{co-4}>T_{co-5}>T_{co-6}>T_{co-7}.

In other words, under the condition that the reference voltage V₀, the reference temperature T₀ and the working temperature T₁ of the memory device are unchanged, the first pass voltage Vₚₐₛₛ₁ is greater than the second pass voltage Vₚₐₛₛ₂, the second pass voltage Vₚₐₛₛ₂ is greater than the third pass voltage Vₚₐₛₛ₃, the third pass voltage Vₚₐₛₛ₃ is greater than the fourth pass voltage Vₚₐₛₛ₄, the fourth pass voltage Vₚₐₛₛ₄ is greater than the fifth pass voltage Vₚₐₛₛ₅, the fifth pass voltage Vₚₐₛₛ₅ is greater than the sixth pass voltage Vₚₐₛₛ₆, and the sixth pass voltage Vₚₐₛₛ₆ is greater than the seventh pass voltage Vₚₐₛₛ₇, e.g., Vₚₐₛₛ₁>Vₚₐₛₛ₂>Vₚₐₛₛ₃>Vₚₐₛₛ₄>Vₚₐₛₛ₅>Vₚₐₛₛ₆>Vₚₐₛₛ₇.

That is to say, under the condition that the reference voltage V₀, the reference temperature T₀ and the working temperature T₁ of the memory device are unchanged, as the threshold voltage corresponding to the storage state gradually increases, the value of the read voltage gradually increases, the corresponding compensation factor gradually decreases, and the value of the compensation voltage gradually decreases, that is, the value of the pass voltage gradually decreases. In other words, under the condition that the reference voltage V₀, the reference temperature T₀ and the working temperature T₁ of the memory device are unchanged, as the threshold voltage corresponding to the storage state gradually decreases, the value of the read voltage gradually decreases, the corresponding compensation factor gradually increases, and the value of the compensation voltage gradually increases, that is, the value of the pass voltage gradually increases.

It is to be noted that the values of the seven pass voltages are all different in the above examples. In some other examples, the values of the seven pass voltages may be partially the same (e.g., some of the compensation factors are the same), but the same pass voltages need to correspond to different bits in the memory cell respectively, such that the need for setting and replacing the compensation factor can be reduced, and the operation efficiency can be improved.

In an example, under the condition that the reference voltage V₀, the reference temperature T₀ and the working temperature T₁ of the memory device are unchanged, when the memory cell is a trinary-level cell (TLC) (e.g., M=3), the memory cell array comprises a lower page, a middle page and an upper page. The read voltage corresponding to the lower page comprises the first read voltage V_{read1} and the fifth read voltage V_{read5}, and a value of the first read voltage V_{read1} is less than a value of the fifth read voltage V_{read5}, e.g., V_{read1}<V_{read5}. The first read voltage V_{read1} corresponds to the first pass voltage Vₚₐₛₛ₁ and the first pass voltage Vₚₐₛₛ₁ corresponds to the first compensation factor T_{co-1}, and the fifth read voltage V_{read5} corresponds to the fifth pass voltage Vₚₐₛₛ₅ and the fifth pass voltage Vₚₐₛₛ₅ corresponds to the fifth compensation factor T_{co-5}. Here, the first compensation factor T_{co-1} is greater than the fifth compensation factor T_{co-5}, e.g., T_{co-1}>T_{co-5}.

The read voltage corresponding to the middle page comprises the second read voltage V_{read2}, the fourth read voltage V_{read4} and the sixth read voltage V_{read6}. A value of the second read voltage V_{read2} is less than a value of the fourth read voltage V_{read4}, and the value of the fourth read voltage V_{read4} is less than a value of the sixth read voltage V_{read6}, e.g., V_{read2}<V_{read4}<V_{read6}. The second read voltage V_{read2} corresponds to the second pass voltage Vₚₐₛₛ₂ and the second pass voltage Vₚₐₛₛ₂ corresponds to the second compensation factor T_{co-2}; the fourth read voltage V_{read4} corresponds to the fourth pass voltage Vₚₐₛₛ₄ and the fourth pass voltage Vₚₐₛₛ₄ corresponds to the fourth compensation factor T_{co-4}; and the sixth read voltage V_{read6} corresponds to the sixth pass voltage Vₚₐₛₛ₆ and the sixth pass voltage Vₚₐₛₛ₆ corresponds to the sixth compensation factor T_{co-6}. Here, the second compensation factor T_{co-2} is greater than the fourth compensation factor T_{co-4}, and the fourth compensation factor T_{co-4} is greater than the sixth compensation factor T_{co-6}, e.g., T_{co-2}>T_{co-4}>T_{co-6}.

The read voltage corresponding to the upper page comprises the third read voltage V_{read3} and the seventh read voltage V_{read7}. A value of the third read voltage V_{read3} is less than a value of the seventh read voltage V_{read7}, e.g., V_{read3}<V_{read7}. The third read voltage V_{read3} corresponds to the third pass voltage Vₚₐₛₛ₃ and the third pass voltage Vₚₐₛₛ₃ corresponds to the third compensation factor T_{co-3}, and the seventh read voltage V_{read7} corresponds to the seventh pass voltage Vₚₐₛₛ₇ and the seventh pass voltage Vₚₐₛₛ₇ corresponds to the seventh compensation factor T_{co-7}. Here, the third compensation factor T_{co-3} is greater than the seventh compensation factor T_{co-7}, e.g., T_{co-3}>T_{co-7}.

Here, the first compensation factor T_{co-1} is equal to the second compensation factor T_{co-2}, e.g., T_{co-1}=T_{co-2}; and/or the second compensation factor T_{co-2} is equal to the third compensation factor T_{co-3}, e.g., T_{co-2}=T_{co-3}.

In some other examples, under the condition that the reference voltage V₀, the reference temperature T₀ and the compensation factor T_{co-n} are unchanged (e.g., the same storage state is read), the pass voltage Vₚₐₛₛ or the compensation voltage V_{c} (e.g., an increment of the pass voltage) is related to the working temperature T₁ of the memory device.

In an example, under the condition that the reference voltage V₀, the reference temperature T₀ and the compensation factor T_{co-n} are unchanged, the compensation voltage V_{c} is inversely proportional to the working temperature T₁ of the memory device. That is, the higher the working temperature T₁ of the memory device is, the smaller the temperature difference between the reference temperature and the working temperature is, and the smaller the compensation voltage V_{c} is, e.g., the smaller the increment of the pass voltage Vₚₐₛₛ is. As such, the influence of the working temperature on the read window may be improved according to different working environments.

In an example, the working temperature of the memory device is 0° C., the reference temperature is 85° C., and the compensation factor is 0.2*10⁻³V/° C. At this point, the compensation voltage V_{c} is (85-0)*0.2*10⁻³=0.017V, e.g., the pass voltage Vₚₐₛₛ=V₀+0.017. That is to say, when the memory device is in a low temperature (lower than the reference temperature, such as 0° C.) environment, the value of the pass voltage Vₚₐₛₛ is greater than the value of the reference voltage V₀. In contrast, when the memory device is in a high temperature (higher than the reference temperature, such as 90° C.) environment, the value of the pass voltage Vₚₐₛₛ is less than the value of the reference voltage V₀ (the value of the compensation voltage is negative at this point). As such, the influence of high temperature or low temperature on the shift of threshold voltage of the memory cell can be improved, the read window can be increased, and the read performance of the memory device can be improved.

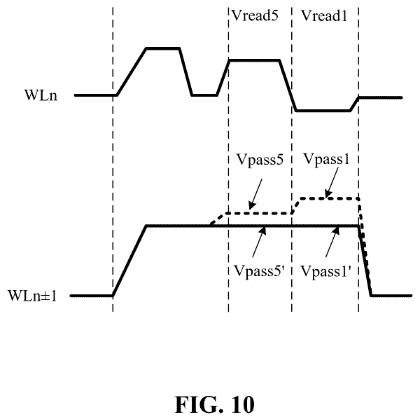

In an example, in conjunction with FIGS. 8 and 10, the dotted line shown in FIG. 10 is a voltage characteristic curve at the working temperature (less than the reference temperature), and the solid line is a voltage characteristic curve at the reference temperature, wherein eight storage states (E, P1, P2, P3, P4, P5, P6, P7) corresponding to the trinary-level cell (TLC) are arranged sequentially from a low storage state to a high storage state respectively. When reading data in the trinary-level cell corresponding to the lower page, the first read voltage V_{read1} is applied to a selected word line (e.g., WLn), the first pass voltage Vₚₐₛₛ₁ is applied to an non-selected word line (e.g., WLn±1), the fifth read voltage V_{read5} is applied to the selected word line WLn, and the fifth pass voltage Vₚₐₛₛ₅ is applied to the non-selected word line WLn±1. The first pass voltage Vₚₐₛₛ₁ at the working temperature is greater than the first pass voltage Vₚₐₛₛ₁′ at the reference temperature, and the fifth pass voltage Vₚₐₛₛ₅ at the working temperature is greater than the fifth pass voltage Vₚₐₛₛ₅′ at the reference temperature. As such, on the one hand, different pass voltages may be applied to the non-selected word line according to different read storage states; and on the other hand, temperature compensations corresponding to different storage states may be controlled separately, so as to reduce the influence of the working temperature on the read window and improve the read performance and reliability of the memory device.

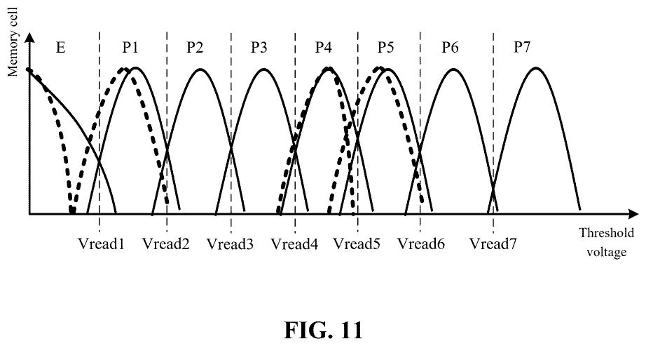

In some other examples, with reference to FIG. 11, the dotted line shown in FIG. 11 is a schematic distribution diagram of the threshold voltages of the memory cell in a conventional operation, the solid line is a schematic distribution diagram of threshold voltages of the memory cell in the examples of the present disclosure, and the value of the pass voltage in the conventional operation is the value of the reference voltage. The value of the pass voltage in the examples of the present disclosure is a sum of the value of the reference voltage and the value of the compensation voltage. As can be seen from FIG. 11, when reading bit data corresponding to the lower page (LP) in the target memory cell, the improvement of read window between the storage state E and the storage state P1 is greater than the improvement of read window between the storage state P4 and the storage state P5, and is more obvious; that is to say, the improvement of low storage state by the compensation voltage is more obvious in the above examples of the present disclosure. On this basis, in some other examples, the compensation voltage may be only added to the corresponding pass voltage when reading the low storage state, so as to improve the read window and balance the read disturbance (SPRD).

In some examples, the non-selected word line adjacent to the selected word line comprises one unselected word line physically located above and/or below the selected word line. In an example, the non-selected word lines adjacent to the selected word line are one unselected word line physically located above the selected word line and one unselected word line physically located below the selected word line. With reference to FIG. 10, the selected word line is labeled as WLn, and the unselected word lines adjacent to the selected word line WLn and physically located above and below the selected word line WLn are labeled as WLn±1.

It is to be noted that during the process of performing the read operation, in addition to applying the pass voltage to the non-selected word line (such as WLn±1) adjacent to the selected word line, a fixed pass voltage may be applied to each of the other non-selected word lines (such as WLn±2, WLn±3, WLn±4 . . . ). That is, the pass voltage is a fixed value, and does not vary with the read voltage/read storage state.

On this basis, in the examples of the present disclosure, when the read operation is performed, the read voltage is applied to the selected word line, and the pass voltage is applied to the non-selected word line adjacent to the selected word line to read data stored in the target memory cell. Further, the pass voltage corresponds to the read voltage, and is related to the working temperature of the memory device and the read storage state when the read operation is performed. As such, during the process of performing the read operation, different pass voltages may be applied to the non-selected word line according to different read voltages and different working temperatures of the memory device, so as to reduce the influence of the working temperature and the read storage state on the read operation, increase the read window, and improve the read performance and reliability of the memory device.

Examples of the present disclosure further provide an operation method of a memory device, comprising: applying a read voltage to a selected word line coupled to a target memory cell of a plurality of memory cells of the memory device and applying a pass voltage to a non-selected word line adjacent to the selected word line when performing a read operation on the target memory cell, wherein the pass voltage is related to the read voltage and a working temperature of the memory device when the read operation is performed.

In some examples, the memory cell is configured to store M bits of data; the plurality of memory cells in the memory cell array have 2^{M} storage states that are distinguished through N orders of read voltage; N=2^{M}−1; and both M and N are integers greater than 1, wherein when the read operation is performed, the N orders of read voltage are applied to the selected word line, N pass voltages are applied to the non-selected word line, the N orders of read voltage have a one-to-one correspondence with the N pass voltages, and values of the N pass voltages are at least partially different.

In some examples, a value of the pass voltage is a sum of a value of a reference voltage and a value of a compensation voltage; and the reference voltage is the pass voltage applied to the non-selected word line when the read operation is performed at a reference temperature, wherein the value of the reference voltage remains unchanged during performing the read operation.

In some examples, the method further comprises: determining the reference temperature and the reference voltage; acquiring the working temperature and determining whether the working temperature is the same as the reference temperature; and determining the value of the compensation voltage, wherein the value of the compensation voltage is a product of a temperature difference between the working temperature and the reference temperature and a compensation factor, wherein the N pass voltages correspond to N compensation voltages that correspond to L compensation factors, and L is an integer greater than 1 and is less than or equal to N.

In some examples, a relationship among the pass voltage, the compensation voltage and the compensation factor is:

Vₚₐₛₛ=V₀+V_{c}=V₀+(T₀−T₁)*T_{co-n}, wherein Vₚₐₛₛ is the pass voltage; V₀ is the reference voltage; V_{c} is the compensation voltage; T₀ is the reference temperature; T₁ is the working temperature; and T_{co-n} is the compensation factor.

In some examples, when M=3, the memory cell array comprises a lower page, a middle page, and an upper page, wherein the read voltage corresponding to the lower page comprises a first read voltage and a fifth read voltage, a value of the first read voltage is less than a value of the fifth read voltage, and a first compensation factor T_{co-1} corresponding to the first read voltage is greater than a fifth compensation factor T_{co-5} corresponding to the fifth read voltage; the read voltage corresponding to the middle page comprises a second read voltage, a fourth read voltage and a sixth read voltage, a value of the second read voltage is less than a value of the fourth read voltage, the value of the fourth read voltage is less than a value of the sixth read voltage, a second compensation factor T_{co-2} corresponding to the second read voltage is greater than a fourth compensation factor T_{co-4} corresponding to the fourth read voltage, and the fourth compensation factor T_{co-4} is greater than a sixth compensation factor T_{co-6} corresponding to the sixth read voltage; and the read voltage corresponding to the upper page comprises a third read voltage and a seventh read voltage, a value of the third read voltage is less than a value of the seventh read voltage, and a third compensation factor T_{co-3} corresponding to the third read voltage is greater than a seventh compensation factor T_{co-7} corresponding to the seventh read voltage.

In some examples, the first compensation factor T_{co-1} is greater than or equal to the second compensation factor T_{co-2}, and the second compensation factor T_{co-2} is greater than or equal to the third compensation factor T_{co-3}.

In some examples, the non-selected word line comprises one unselected word line physically located above and/or below the selected word line.

Examples of the present disclosure further provide a memory system, comprising: one or more memory devices as described in the above examples of the present disclosure; and a memory controller coupled with the memory devices and configured to control the memory devices.

In some examples, the memory system comprises a Universal Flash Storage (UFS) or a solid state disk, and the memory device comprises a NAND memory.

Examples of the present disclosure further provide a storage medium which stores an executable instruction thereon. When the executable instruction is executed by the memory controller, the operation method in the above examples of the present disclosure can be implemented.

In some particular examples, the storage medium may be a Ferromagnetic Random Access Memory (FRAM), a Read Only Memory (ROM), a Programmable Read-Only Memory (PROM), an Erasable Programmable Read-Only Memory (EPROM), an Electrically Erasable Programmable Read-Only Memory (EEPROM), a Flash Memory, a magnetic surface memory, an optical disk, or a CD-ROM (Compact Disc Read-Only Memory) and other memories, or various apparatuses comprising any one or any combination of the above memory devices.

In some examples, the executable instruction may be compiled in any form of programming language (including a compiling or interpreting language, or a declarative or procedural language) by adopting the form of program, software, software module, script or code; and it may be deployed in any form, including being deployed as an independent program or as a module, a component, a subroutine, or other units suitable for use in computing environment.

As an example, the executable instruction may, but does not necessarily, correspond to files in a file system, may be stored in part of a file storing other programs or data, for example, stored in one or more scripts in a Hyper Text Markup Language (HTML) document, stored in a single file dedicated to the discussed program, or stored in a plurality of collaborative files (e.g., the file that stores one or more modules, subprograms or code portions).

As an example, the executable instruction may be deployed to be executed on an electronic apparatus, or to be executed on multiple electronic apparatuses at one site, or to be executed on multiple electronic apparatuses distributed at multiple sites and interconnected through a communication network.

It should be understood that, references to “one example” or “an example” throughout this specification mean that specific features, structures, or characteristics related to the example are included in at least one example of the present disclosure. Therefore, “in one example” or “in an example” presented everywhere throughout this specification does not necessarily refer to the same example. In addition, these specific features, structures or characteristics may be combined in one or more examples in any proper manner. It is to be understood that, in various examples of the present disclosure, sequence numbers of the above processes do not indicate an execution sequence, and an execution sequence of various processes shall be determined by functionalities and intrinsic logics thereof, and shall constitute no limitation on an implementation process of the examples of the present disclosure. The above sequence numbers of the examples of the present disclosure are only for description, and do not represent advantages or disadvantages of the examples.

The methods disclosed in several method examples provided by the present disclosure can be combined arbitrarily to obtain a new method example without conflicts.

On this basis, examples of the present disclosure provide a memory device and an operation method thereof, a memory system and a storage medium. Example of the present disclosure provide a memory device which comprises a memory cell array comprising a plurality of memory cells, and a peripheral circuit coupled with the memory cell array and configured to apply a read voltage to a selected word line coupled to a target memory cell of the plurality of memory cells and apply a pass voltage to a non-selected word line adjacent to the selected word line when performing a read operation on the target memory cell, wherein the pass voltage is related to the read voltage and a working temperature of the memory device when the read operation is performed.

In some examples, the memory cell is configured to store M bits of data; the plurality of memory cells in the memory cell array have 2^{M} storage states that are distinguished through N orders of read voltage; N=2^{M}−1; and both M and N are integers greater than 1, wherein when the read operation is performed, the N orders of read voltage are applied to the selected word line, N pass voltages are applied to the non-selected word line, each order of read voltage corresponds to one pass voltage, and values of the N pass voltages are at least partially different.

In some examples, a value of the pass voltage is a sum of a value of a reference voltage and a value of a compensation voltage; and the reference voltage is the pass voltage applied to the non-selected word line when the read operation is performed at a reference temperature, wherein the value of the reference voltage remains unchanged during a process of performing the read operation.

In some examples, the peripheral circuit is further configured to: determine the reference temperature and the reference voltage; acquire the working temperature and determine a temperature difference between the working temperature and the reference temperature; and determine the value of the compensation voltage, wherein the value of the compensation voltage is a product of the temperature difference between the working temperature and the reference temperature and a compensation factor, wherein the N pass voltages correspond to N compensation voltages that correspond to L compensation factors, and L is an integer greater than 1 and is less than or equal to N.

In some examples, a relationship among the pass voltage, the compensation voltage and the compensation factor is: Vₚₐₛₛ=V₀+V_{c}=V₀+(T₀−T₁)*T_{co-n}, wherein Vₚₐₛₛ is the pass voltage; V₀ is the reference voltage; V_{c} is the compensation voltage; T₀ is the reference temperature; T₁ is the working temperature; and T_{co-n}, is the compensation factor.

In some examples, when M=3, the memory cell array comprises a lower page, a middle page and an upper page; a read voltage corresponding to the lower page comprises a first read voltage and a fifth read voltage, a value of the first read voltage is less than a value of the fifth read voltage, and a first compensation factor T_{co-1} corresponding to the first read voltage is greater than a fifth compensation factor T_{co-5} corresponding to the fifth read voltage; a read voltage corresponding to the middle page comprises a second read voltage, a fourth read voltage and a sixth read voltage, a value of the second read voltage is less than a value of the fourth read voltage, a value of the fourth read voltage is less than a value of the sixth read voltage, a second compensation factor T_{co-2} corresponding to the second read voltage is greater than a fourth compensation factor T_{co-4} corresponding to the fourth read voltage, and the fourth compensation factor T_{co-4} is greater than a sixth compensation factor T_{co-6} corresponding to the sixth read voltage; and a read voltage corresponding to the upper page comprises a third read voltage and a seventh read voltage, a value of the third read voltage is less than a value of the seventh read voltage, and a third compensation factor T_{co-3} corresponding to the third read voltage is greater than a seventh compensation factor T_{co-7} corresponding to the seventh read voltage.

In some examples, the first compensation factor T_{co-1} is greater than or equal to the second compensation factor T_{co-2}, and the second compensation factor T_{co-2} is greater than or equal to the third compensation factor T_{co-3}.

In some examples, the non-selected word line comprises one unselected word line physically located above and/or below the selected word line.

In some examples, the memory device comprises a three-dimensional NAND memory.

Examples of the present disclosure further provide a memory system, comprising: one or more memory devices as described in the above examples of the present disclosure; and a memory controller coupled with the memory devices and configured to control the memory devices.

Examples of the present disclosure further provide an operation method of a memory device, comprising: applying a read voltage to a selected word line coupled to a target memory cell of a plurality of memory cells of the memory device and applying a pass voltage to a non-selected word line adjacent to the selected word line when performing a read operation on the target memory cell, wherein the pass voltage is related to the read voltage and a working temperature of the memory device when the read operation is performed.

In some examples, the memory cell is configured to store M bits of data; the plurality of memory cells in the memory cell array have 2^{M} storage states that are distinguished through N orders of read voltage; N=2^{M}−1; and both M and N are integers greater than 1, wherein when the read operation is performed, the N orders of read voltage are applied to the selected word line, N pass voltages are applied to the non-selected word line, the N orders of read voltage have a one-to-one correspondence with the N pass voltages, and values of the N pass voltages are at least partially different.

In some examples, a value of the pass voltage is a sum of a value of a reference voltage and a value of a compensation voltage; and the reference voltage is the pass voltage applied to the non-selected word line when the read operation is performed at a reference temperature, wherein the value of the reference voltage remains unchanged during a process of performing the read operation.

In some examples, the method further comprises: determining the reference temperature and the reference voltage; acquiring the working temperature and determining whether the working temperature is the same as the reference temperature; and determining the value of the compensation voltage, wherein the value of the compensation voltage is a product of a temperature difference between the working temperature and the reference temperature and a compensation factor, wherein the N pass voltages correspond to N compensation voltages that correspond to L compensation factors, and L is an integer greater than 1 and is less than or equal to N.

In some examples, a relationship among the pass voltage, the compensation voltage and the compensation factor is: Vₚₐₛₛ=V₀+V_{c}=V₀+(T₀-T₁)*T_{co-n}, wherein Vₚₐₛₛ is the pass voltage; V₀ is the reference voltage; V_{c} is the compensation voltage; To is the reference temperature; T₁ is the working temperature; and T_{co-n} is the compensation factor.

In some examples, when M=3, the memory cell array comprises a lower page, a middle page and an upper page; a read voltage corresponding to the lower page comprises a first read voltage and a fifth read voltage, a value of the first read voltage is less than a value of the fifth read voltage, and a first compensation factor T_{co-1} corresponding to the first read voltage is greater than a fifth compensation factor T_{co-5} corresponding to the fifth read voltage; a read voltage corresponding to the middle page comprises a second read voltage, a fourth read voltage and a sixth read voltage, a value of the second read voltage is less than a value of the fourth read voltage, a value of the fourth read voltage is less than a value of the sixth read voltage, a second compensation factor T_{co-2} corresponding to the second read voltage is greater than a fourth compensation factor T_{co-4} corresponding to the fourth read voltage, and the fourth compensation factor T_{co-4} is greater than a sixth compensation factor T_{co-6} corresponding to the sixth read voltage; and a read voltage corresponding to the upper page comprises a third read voltage and a seventh read voltage, a value of the third read voltage is less than a value of the seventh read voltage, and a third compensation factor T_{co-3} corresponding to the third read voltage is greater than a seventh compensation factor T_{co-7} corresponding to the seventh read voltage.

In some examples, the first compensation factor T_{co-1} is greater than or equal to the second compensation factor T_{co-2}, and the second compensation factor T_{co-2} is greater than or equal to the third compensation factor T_{co-3}.

In some examples, the non-selected word line comprises one unselected word line physically located above and/or below the selected word line.

Examples of the present disclosure further provide a storage medium which stores an executable instruction thereon. When the executable instruction is executed by the memory controller, the operation method in the above examples of the present disclosure is implemented.

In the examples of the present disclosure, when the read operation is performed, the read voltage is applied to the selected word line, and the pass voltage is applied to the non-selected word line adjacent to the selected word line to read data stored in the target memory cell. Further, the pass voltage corresponds to the read voltage, and is related to the working temperature of the memory device when the read operation is performed. As such, during the process of performing the read operation, different pass voltages may be applied to the non-selected word line according to different read voltages and different working temperatures of the memory device, so as to reduce the influence of temperature on the read operation, increase the read window and improve the read performance and reliability of the memory device.

The above descriptions are merely specific implementations of the present disclosure, and the protection scope of the present disclosure is not limited thereto. Any variation or replacement that may be readily figured out by those skilled in the art within the technical scope disclosed by the present disclosure should fall within the protection scope of the present disclosure. Therefore, the protection scope of the present disclosure shall be defined by the protection scope of the claims.

What is claimed is:

1. A memory device, comprising:
a memory cell array including a plurality of memory cells; and
a peripheral circuit coupled with the memory cell array and configured to:
apply a read voltage to a selected word line coupled to a target memory cell of the plurality of memory cells and apply a pass voltage to a non-selected word line adjacent to the selected word line when performing a read operation on the target memory cell,
wherein the pass voltage is related to the read voltage and a working temperature of the memory device when the read operation is performed.

2. The memory device of claim 1, wherein the memory cell is configured to store M bits of data; the plurality of memory cells in the memory cell array have 2^{M} storage states that are distinguished through N orders of read voltage; N=2^{M}−1; and both M and N are integers greater than 1,
wherein when the read operation is performed, the N orders of read voltage are applied to the selected word line, N pass voltages are applied to the non-selected word line, each order of read voltage corresponds to one pass voltage, and values of the N pass voltages are at least partially different.

3. The memory device of claim 2, wherein a value of the pass voltage is a sum of a value of a reference voltage and a value of a compensation voltage; and the reference voltage is the pass voltage applied to the non-selected word line when the read operation is performed at a reference temperature,
wherein the value of the reference voltage remains unchanged during a process of performing the read operation.

4. The memory device of claim 3, wherein the peripheral circuit is further configured to:
determine the reference temperature and the reference voltage;
acquire the working temperature and determine a temperature difference between the working temperature and the reference temperature; and
determine the value of the compensation voltage, wherein the value of the compensation voltage is a product of the temperature difference between the working temperature and the reference temperature and a compensation factor,
wherein the N pass voltages correspond to N compensation voltages that correspond to L compensation factors, and L is an integer greater than 1 and is less than or equal to N.

5. The memory device of claim 4, wherein a relationship among the pass voltage, the compensation voltage and the compensation factor is:
$${V}_{pass} = {V}_{0} + {V}_{c} = {V}_{0} + {( {T}_{0} - {T}_{1} )}^{*} {T}_{co - n}$$
wherein Vₚₐₛₛ is the pass voltage; V₀ is the reference voltage; V_{c} is the compensation voltage; T₀ is the reference temperature; T₁ is the working temperature; and T_{co-n} is the compensation factor.

6. The memory device of claim 5, wherein when M=3, the memory cell array comprises a lower page, a middle page and an upper page;
a read voltage corresponding to the lower page includes a first read voltage and a fifth read voltage, a value of the first read voltage is less than a value of the fifth read voltage, and a first compensation factor T_{co-1} corresponding to the first read voltage is greater than a fifth compensation factor T_{co-5} corresponding to the fifth read voltage;
a read voltage corresponding to the middle page includes a second read voltage, a fourth read voltage and a sixth read voltage, a value of the second read voltage is less than a value of the fourth read voltage, a value of the fourth read voltage is less than a value of the sixth read voltage, a second compensation factor T_{co-2} corresponding to the second read voltage is greater than a fourth compensation factor T_{co-4} corresponding to the fourth read voltage, and the fourth compensation factor T_{co-4} is greater than a sixth compensation factor T_{co-6} corresponding to the sixth read voltage; and
a read voltage corresponding to the upper page includes a third read voltage and a seventh read voltage, a value of the third read voltage is less than a value of the seventh read voltage, and a third compensation factor T_{co-3} corresponding to the third read voltage is greater than a seventh compensation factor T_{co-7} corresponding to the seventh read voltage.

7. The memory device of claim 6, wherein the first compensation factor T_{co-1} is greater than or equal to the second compensation factor T_{co-2}, and the second compensation factor T_{co-2} is greater than or equal to the third compensation factor T_{co-3}.

8. The memory device of claim 1, wherein the non-selected word line includes one unselected word line physically located above and/or below the selected word line.

9. The memory device of claim 1, including a three-dimensional NAND memory.

10. A memory system, comprising:
one or more memory devices, including:
a memory cell array including a plurality of memory cells; and
a peripheral circuit coupled with the memory cell array and configured to:
apply a read voltage to a selected word line coupled to a target memory cell of the plurality of memory cells and apply a pass voltage to a non-selected word line adjacent to the selected word line when performing a read operation on the target memory cell, wherein the pass voltage is related to the read voltage and a working temperature of the memory device when the read operation is performed; and
a memory controller coupled with the memory devices and configured to control the memory devices.

11. An operation method of a memory device, comprising:
applying a read voltage to a selected word line coupled to a target memory cell of a plurality of memory cells of the memory device and applying a pass voltage to a non-selected word line adjacent to the selected word line when performing a read operation on the target memory cell,
wherein the pass voltage is related to the read voltage and a working temperature of the memory device when the read operation is performed.

12. The operation method of claim 11, wherein the memory cell is configured to store M bits of data; the plurality of memory cells have 2^{M} storage states that are distinguished through N orders of read voltage; N=2^{M}−1; and both M and N are integers greater than 1,
wherein when the read operation is performed, the N orders of read voltage are applied to the selected word line, N pass voltages are applied to the non-selected word line, the N orders of read voltage have a one-to-one correspondence with the N pass voltages, and values of the N pass voltages are at least partially different.

13. The operation method of claim 12, wherein a value of the pass voltage is a sum of a value of a reference voltage and a value of a compensation voltage; and the reference voltage is the pass voltage applied to the non-selected word line when the read operation is performed at a reference temperature,
wherein the value of the reference voltage remains unchanged during a process of performing the read operation.

14. The operation method of claim 13, further including:
determining the reference temperature and the reference voltage;
acquiring the working temperature and determining whether the working temperature is the same as the reference temperature; and
determining the value of the compensation voltage, wherein the value of the compensation voltage is a product of a temperature difference between the working temperature and the reference temperature and a compensation factor, wherein the N pass voltages correspond to N compensation voltages that correspond to L compensation factors, and L is an integer greater than 1 and is less than or equal to N.

15. The operation method of claim 14, wherein a relationship among the pass voltage, the compensation voltage and the compensation factor is:
$${V}_{pass} = {V}_{0} + {V}_{c} = {V}_{0} + {( {T}_{0} - {T}_{1} )}^{*} {T}_{co - n}$$
wherein Vₚₐₛₛ is the pass voltage; V₀ is the reference voltage; V_{c} is the compensation voltage; T₀ is the reference temperature; T₁ is the working temperature; and T_{co-n} is the compensation factor.

16. The operation method of claim 15, wherein when M=3, the plurality of memory cells includes a lower page, a middle page and an upper page;
a read voltage corresponding to the lower page includes a first read voltage and a fifth read voltage, a value of the first read voltage is less than a value of the fifth read voltage, and a first compensation factor T_{co-1} corresponding to the first read voltage is greater than a fifth compensation factor T_{co-5} corresponding to the fifth read voltage;
a read voltage corresponding to the middle page includes a second read voltage, a fourth read voltage and a sixth read voltage, a value of the second read voltage is less than a value of the fourth read voltage, a value of the fourth read voltage is less than a value of the sixth read voltage, a second compensation factor T_{co-2} corresponding to the second read voltage is greater than a fourth compensation factor T_{co-4} corresponding to the fourth read voltage, and the fourth compensation factor T_{co-4} is greater than a sixth compensation factor T_{co-6} corresponding to the sixth read voltage; and
a read voltage corresponding to the upper page includes a third read voltage and a seventh read voltage, a value of the third read voltage is less than a value of the seventh read voltage, and a third compensation factor T_{co-3} corresponding to the third read voltage is greater than a seventh compensation factor T_{co-7} corresponding to the seventh read voltage.

17. The operation method of claim 16, wherein the first compensation factor T_{co-1} is greater than or equal to the second compensation factor T_{co-2}, and the second compensation factor T_{co-2} is greater than or equal to the third compensation factor T_{co-3}.

18. The operation method of claim 11, wherein the non-selected word line includes one unselected word line physically located above and/or below the selected word line.
